(19) United States
(12) Patent Application Publication
(10) Pub. No.: US 2021/0249580 A1
(43) Pub. Date: Aug. 12, 2021

(54) FLEXIBLE ENCAPSULATION OF A FLEXIBLE THIN-FILM BASED THERMOELECTRIC DEVICE WITH SPUTTER DEPOSITED LAYER OF N-TYPE AND P-TYPE THERMOELECTRIC LEGS

(71) Applicant: Sridhar Kasichainula, Fremont, CA (US)

(72) Inventor: Sridhar Kasichainula, Fremont, CA (US)

(21) Appl. No.: 17/243,538

(22) Filed: Apr. 28, 2021

Related U.S. Application Data
(63) Continuation-in-part of application No. 16/721,878, filed on Dec. 19, 2019, now Pat. No. 11,024,789.
Application No. 16/721,878 is a continuation-in-part of application No. 15/869,017, filed on Jan. 11, 2018, now Pat. No. 10,553,773.
Application No. 15/869,017 is a continuation-in-part of application No. 14/711,810, filed on May 14, 2015, now Pat. No. 10,141,492.

(51) Int. Cl. H01L 35/34; H01L 35/10; H01L 35/32

(52) U.S. Cl. CPC H01L 35/34; H01L 35/16; H01L 35/32; H01L 35/10

(57) ABSTRACT

A method includes etching and patterning a metal cladding of a metal clad laminate to form electrically conductive pads, leads and terminals therewith across a surface of the metal clad laminate, and sputter depositing pairs of N-type thermoelectric legs and P-type thermoelectric legs electrically in contact with one another on top of the formed electrically conductive pads across the surface of the metal clad laminate. The method also includes depositing conductive interconnects directly on top of a barrier metal layer above the pairs of the N-type thermoelectric legs and the P-type thermoelectric legs to connect all of the pairs of the N-type thermoelectric legs and the P-type thermoelectric legs to one another to form the thermoelectric module, and utilizing a temperature gradient perpendicular to a plane of the surface of the metal clad laminate of the formed thermoelectric module to derive thermoelectric power from a system element.

### CLAIM OF PRIORITY

This application is a continuation-in-part application of co-pending U.S. patent application Ser. No. 16/721,878 titled FLEXIBLE ENCAPSULATION OF A FLEXIBLE THIN-FILM BASED THERMOELECTRIC DEVICE WITH SPUTTER DEPOSITED LAYER OF N-TYPE AND P-TYPE THERMOELECTRIC LEGS filed on Dec. 19, 2019, which is a continuation-in-part application of U.S. patent application Ser. No. 15/869,017 also titled FLEXIBLE ENCAPSULATION OF A FLEXIBLE THIN-FILM BASED THERMOELECTRIC DEVICE WITH SPUTTER DEPOSITED LAYER OF N-TYPE AND P-TYPE THERMOELECTRIC LEGS filed on Jan. 11, 2018 and issued as U.S. Pat. No. 10,553,773 on Feb. 4, 2020, which is a continuation-in-part application of co-pending U.S. patent application Ser. No. 15/808,902 titled FLEXIBLE THIN-FILM BASED THERMOELECTRIC DEVICE WITH SPUTTER DEPOSITED LAYER OF N-TYPE AND P-TYPE THERMOELECTRIC LEGS filed on Nov. 10, 2017, U.S. patent application Ser. No. 14/564,072 titled VOLTAGE GENERATION ACROSS TEMPERATURE DIFFERENTIALS THROUGH A THERMOELECTRIC LAYER COMPOSITE filed on Dec. 8, 2014, which is a conversion application of U.S. Provisional Application No. 61/912,561 also titled VOLTAGE GENERATION ACROSS TEMPERATURE DIFFERENTIALS THROUGH A THERMOELECTRIC LAYER COMPOSITE filed on Dec. 6, 2013, U.S. patent application Ser. No. 14/711,810 titled ENERGY HARVESTING FOR WEARABLE TECHNOLOGY

THROUGH A THIN FLEXIBLE THERMOELECTRIC DEVICE filed on May 14, 2015 and issued as U.S. Pat. No. 10,141,492 on Nov. 27, 2018, and U.S. patent application Ser. No. 15/368,683 titled PIN COUPLING BASED THERMOELECTRIC DEVICE filed on Dec. 5, 2016 and issued as U.S. Pat. No. 10,290,794 on May 14, 2019. The contents of the aforementioned applications are incorporated by reference in entirety thereof.

### FIELD OF TECHNOLOGY

This disclosure relates generally to thermoelectric devices and, more particularly, to flexible encapsulation of a flexible thin-film based thermoelectric device with a sputter deposited layer of N-type and P-type thermoelectric legs.

### BACKGROUND

A thermoelectric device may be formed from alternating N and P elements/legs made of semiconducting material on a rigid substrate (e.g., alumina) joined on a top thereof to another rigid substrate/plate (e.g., again, alumina). In certain applications, ceramic enclosure(s) may encapsulate the aforementioned thermoelectric device. However, a traditional implementation of the thermoelectric device may be limited in application thereof because of rigidity, bulkiness, size and high costs (>$20/watt) associated therewith. In addition, the ceramic enclosure(s) and the substrate rigidity may compromise a flexibility of the thermoelectric device.

### SUMMARY

Disclosed are methods, a device and/or a system of flexible encapsulation of a flexible thin-film based thermoelectric device with a sputter deposited layer of N-type and P-type thermoelectric legs.

In one aspect, a method of a thermoelectric module includes straightening out a metal clad laminate previously in a rolled sheet form thereof, etching and patterning a metal cladding of the metal clad laminate to form electrically conductive pads, leads and terminals therewith across a surface of the metal clad laminate following the straightening, and sputter depositing a number of pairs of N-type thermoelectric legs and P-type thermoelectric legs electrically in contact with one another on top of the formed electrically conductive pads across the surface of the metal clad laminate. Each electrically conductive lead establishes electrical contact between a pair of electrically conductive pads.

The method also includes sputter depositing a barrier metal layer on top of the number of pairs of the N-type thermoelectric legs and the P-type thermoelectric legs to further aid metallization contact therewith, depositing conductive interconnects directly on top of the sputter deposited barrier metal layer to connect all of the number of pairs of the N-type thermoelectric legs and the P-type thermoelectric legs to one another to form the thermoelectric module, and utilizing a temperature gradient perpendicular to a plane of the surface of the metal clad laminate of the formed thermoelectric module to derive thermoelectric power from a system element.

In another aspect, a method of a thermoelectric module includes straightening out a metal clad laminate previously in a rolled sheet form thereof, etching and patterning a metal cladding of the metal clad laminate to form electrically conductive pads, leads and terminals therewith across a surface of the metal clad laminate following the straightening, and sputter depositing a number of pairs of N-type thermoelectric legs and P-type thermoelectric legs electrically in contact with one another on top of the formed electrically conductive pads across the surface of the metal clad laminate. Each electrically conductive lead establishes electrical contact between a pair of electrically conductive pads.

The method also includes sputter depositing a barrier metal layer including Chromium (Cr), Nickel (Ni) or Gold (Au) on top of the number of pairs of the N-type thermoelectric legs and the P-type thermoelectric legs to further aid metallization contact therewith, depositing conductive interconnects directly on top of the sputter deposited barrier metal layer to connect all of the number of pairs of the N-type thermoelectric legs and the P-type thermoelectric legs to one another to form the thermoelectric module, and utilizing a temperature gradient perpendicular to a plane of the surface of the metal clad laminate of the formed thermoelectric module to derive thermoelectric power from a system element.

In yet another aspect, a method of a thermoelectric module includes straightening out a metal clad laminate previously in a rolled sheet form thereof, etching and patterning a metal cladding of the metal clad laminate to form electrically conductive pads, leads and terminals therewith across a surface of the metal clad laminate following the straightening, and sputter depositing a number of pairs of N-type thermoelectric legs and P-type thermoelectric legs electrically in contact with one another on top of the formed electrically conductive pads across the surface of the metal clad laminate. Each electrically conductive lead establishes electrical contact between a pair of electrically conductive pads.

The method also includes sputter depositing a barrier metal layer on top of the number of pairs of the N-type thermoelectric legs and the P-type thermoelectric legs to further aid metallization contact therewith, depositing conductive interconnects directly on top of the sputter deposited barrier metal layer to connect all of the number of pairs of the N-type thermoelectric legs and the P-type thermoelectric legs to one another to form the thermoelectric module, encapsulating the formed thermoelectric module with an elastomer to render flexibility thereto, and utilizing a temperature gradient perpendicular to a plane of the surface of the metal clad laminate of the formed thermoelectric module to derive thermoelectric power from a system element.

Other features will be apparent from the accompanying drawings and from the detailed description that follows.

### BRIEF DESCRIPTION OF THE DRAWINGS

The embodiments of this invention are illustrated by way of example and not limitation in the figures of the accompanying drawings, in which like references indicate similar elements and in which:

FIG. 1 is a schematic view of a thermoelectric device.

FIG. 2 is a schematic view of an example thermoelectric device with alternating P and N elements.

FIG. 3 is a top schematic view of a thermoelectric device component, according to one or more embodiments.

FIG. 4 is a process flow diagram detailing the operations involved in realizing a patterned flexible substrate of a thermoelectric device as per a design pattern, according to one or more embodiments.

FIG. 5 is a schematic view of the patterned flexible substrate of FIG. 4, according to one or more embodiments.

FIG. 6 is a schematic view of the patterned flexible substrate of FIG. 4 with N-type thermoelectric legs, P-type thermoelectric legs, a barrier layer and conductive interconnects, according to one or more embodiments.

FIG. 7 is a process flow diagram detailing the operations involved in sputter deposition of the N-type thermoelectric legs of FIG. 6 on the patterned flexible substrate (or, a seed metal layer) of FIG. 5, according to one or more embodiments.

FIG. 8 is a process flow diagram detailing the operations involved in deposition of the barrier layer of FIG. 6 on top of the sputter deposited pairs of P-type thermoelectric legs and the N-type thermoelectric legs of FIG. 6 and forming the conductive interconnects of FIG. 6 on top of the barrier layer, according to one or more embodiments.

FIG. 9 is a process flow diagram detailing the operations involved in encapsulating the thermoelectric device of FIG. 4 and FIG. 6, according to one or more embodiments.

FIG. 10 is a schematic view of a flexible thermoelectric device embedded within a watch strap of a watch completely wrappable around a wrist of a human being.

FIG. 11 is a schematic view of a flexible thermoelectric device wrapped around a heat pipe.

FIG. 12 is a schematic view of a thermoelectric device with elastomer encapsulation, according to one or more embodiments.

FIG. 13 is a schematic view of deposition of a barrier film prior to application of an elastomer to encapsulate the thermoelectric device of FIG. 12, according to one or more embodiments.

FIG. 14 is a schematic view of flexibility and bendability of an example thermoelectric device in accordance with the embodiment of FIG. 12.

FIG. 15 is a process flow diagram detailing the operations involved in flexibly encapsulating a flexible thin-film based thermoelectric module with sputter deposited N-type and P-type thermoelectric legs, according to one or more embodiments.

FIG. 16 is a schematic view of a traditional bulk thermoelectric module.

Other features of the present embodiments will be apparent from the accompanying drawings and from the detailed description that follows.

### DETAILED DESCRIPTION

Example embodiments, as described below, may be used to provide methods, a device and/or a system of flexible encapsulation of a flexible thin-film based thermoelectric device with a sputter deposited layer of N-type and P-type thermoelectric legs. Although the present embodiments have been described with reference to specific example embodiments, it will be evident that various modifications and changes may be made to these embodiments without departing from the broader spirit and scope of the various embodiments.

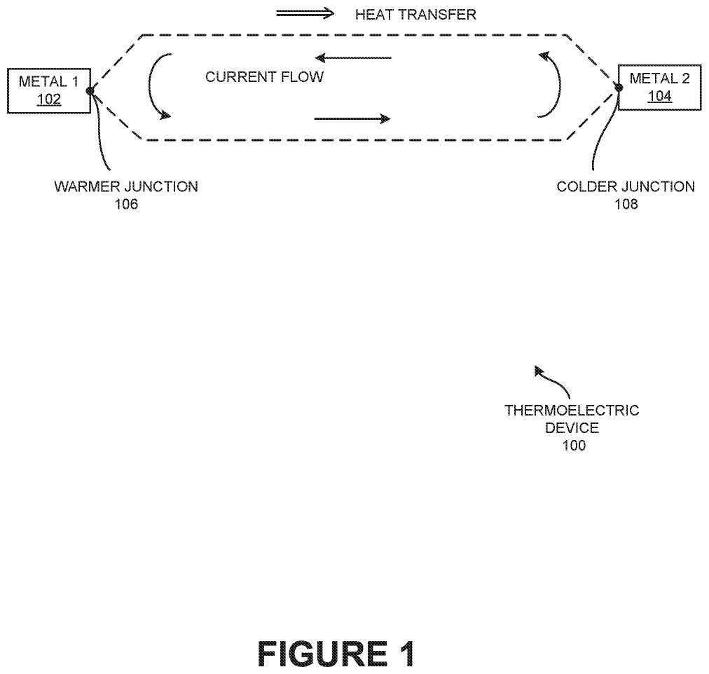

FIG. 1 shows a thermoelectric device 100. Thermoelectric device 100 may include different metals, metal 1 102 and metal 2 104, forming a closed circuit. Here, a temperature difference between junctions of said dissimilar metals leads to energy levels of electrons therein shifted in a dissimilar manner. This results in a potential/voltage difference between the warmer (e.g., warmer junction 106) of the junctions and the colder (e.g., colder junction 108) of the junctions. The aforementioned conversion of heat into electricity at junctions of dissimilar metals is known as Seebeck effect.

The most common thermoelectric devices in the market may utilize alternative P and N type legs/pellets/elements made of semiconducting materials. As heat is applied to one end of a thermoelectric device based on P and N type elements, charge carriers thereof may be released into the conduction band. Electron (charge carrier) flow in the N type element may contribute to a current flowing from the end (hot end) where the heat is applied to the other end (cold end). Hole (charge carrier) flow in the P type element may contribute to a current flowing from the other end (cold end) to the end (hot end) where the heat is applied. Here, heat may be removed from the cold end to prevent equalization of charge carrier distribution in the semiconductor materials due to migration thereof.

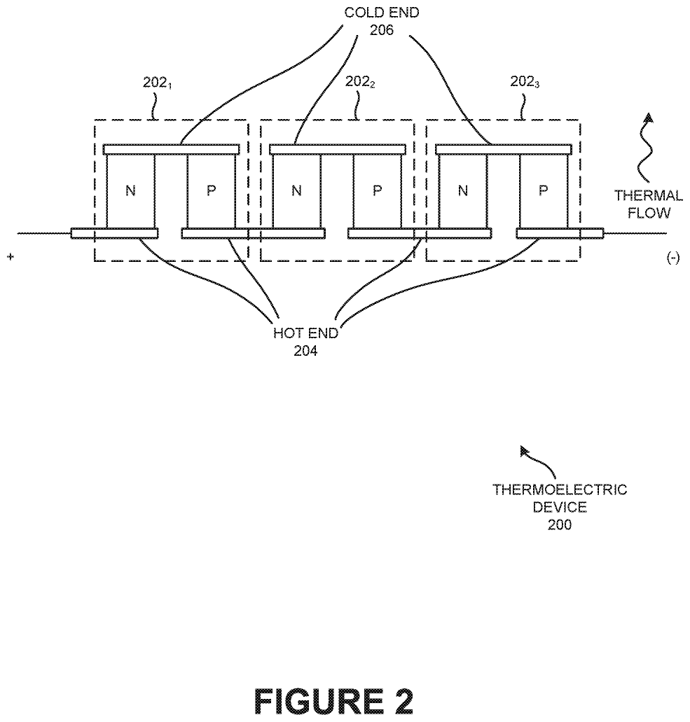

In order to generate voltage at a meaningful level to facilitate one or more application(s), typical thermoelectric devices may utilize alternating P and N type elements (legs/pellets) electrically coupled in series (and thermally coupled in parallel) with one another, as shown in FIG. 2. FIG. 2 shows an example thermoelectric device 200 including three alternating P and N type elements 202₁₋₃. The hot end (e.g., hot end 204) where heat is applied and the cold end (e.g., cold end 206) are also shown in FIG. 2.

Typical thermoelectric devices (e.g., thermoelectric device 200) may be limited in application thereof because of rigidity, bulkiness and high costs (>$20/watt) associated therewith. Also, these devices may operate at high temperatures using active cooling. Exemplary embodiments discussed herein provide for a thermoelectric platform (e.g., enabled via roll-to-roll sputtering on a flexible substrate (e.g., plastic)) that offers a large scale, commercially viable, high performance, easy integration and inexpensive (<20 cents/watt) route to flexible thermoelectrics.

In accordance with the exemplary embodiments, P and N thermoelectric legs may be deposited on a flexible substrate (e.g., plastic) using a roll-to-roll process that offers scalability and cost savings associated with the N and P materials. In a typical solution, bulk legs may have a height in millimeters (mm) and an area in mm². In contrast, N and P bulk legs described in the exemplary embodiments discussed herein may have a height in microns (μm) and an area in the μm² to mm² range.

Examples of flexible substrates may include but are not limited to aluminum (Al) foil, a sheet of paper, teflon, plastic and a single/double-sided copper (Cu) clad laminate sheet. As will be discussed below, exemplary embodiments involve processes for manufacturing/fabrication of thermoelectric devices/modules that enable flexibility thereof not only in terms of substrates but also in terms of thin films/thermoelectric legs/interconnects/packaging. Preferably, exemplary embodiments provide for thermoelectric devices/modules completely wrappable and bendable around other devices utilized in specific applications, as will be discussed below. Further, exemplary embodiments provide for manufactured/fabricated thermoelectric devices/modules that are each less than or equal to 100 μm in dimensional thickness.

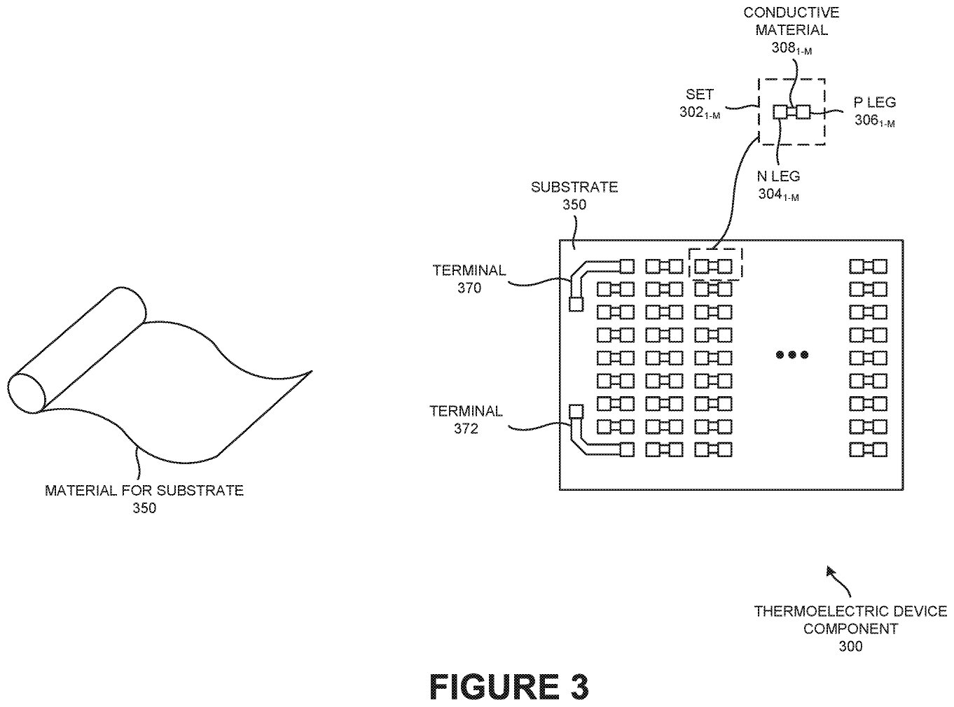

FIG. 3 shows a top view of a thermoelectric device component 300, according to one or more embodiments. Here, in one or more embodiments, a number of sets of N and P legs (e.g., sets 302_{1-M} including N legs 304_{1-M} and P legs 306_{1-M} therein) may be deposited on a substrate 350 (e.g., plastic, Cu clad laminate sheet) using a roll-to-roll process discussed above. FIG. 3 also shows a conductive material 308_{1-M} contacting both a set 302_{1-M} and substrate 350, according to one or more embodiments; an N leg 304_{1-M} and a P leg 306_{1-M} form a set 302_{1-M}, in which N leg 304_{1-M} and P leg 306_{1-M} electrically contact each other through conductive material 308_{1-M}. Terminals 370 and 372 may be electrically conductive leads to measure the potential difference generated by a thermoelectric device including thermoelectric device component 300.

Exemplary thermoelectric devices discussed herein may find utility in solar and solar thermal applications. As discussed above, traditional thermoelectric devices may have a size limitation and may not scale to a larger area. For example, a typical solar panel may have an area in the square meter (m²) range and the traditional thermoelectric device may have an area in the square inch range. A thermoelectric device in accordance with the exemplary embodiments may be of varying sizes and/or dimensions ranging from a few mm² to a few m².

Additionally, exemplary thermoelectric devices may find use in low temperature applications such as harvesting body heat in a wearable device, automotive devices/components and Internet of Things (IoT). Entities (e.g., companies, start-ups, individuals, conglomerates) may possess expertise to design and/or develop devices that require thermoelectric modules, but may not possess expertise in the fabrication and packaging of said thermoelectric modules. Alternately, even though the entities may possess the requisite expertise in the fabrication and packaging of the thermoelectric modules, the entities may not possess a comparative advantage with respect to the aforementioned processes.

In one scenario, an entity may create or possess a design pattern for a thermoelectric device. Said design pattern may be communicated to another entity associated with a thermoelectric platform to be tangibly realized as a thermoelectric device. It could also be envisioned that the another entity may provide training with regard to the fabrication processes to the one entity or outsource aspects of the fabrication processes to a third-party. Further, the entire set of processes involving Intellectual Property (IP) generation and manufacturing/fabrication of the thermoelectric device may be handled by a single entity. Last but not the least, the entity may generate the IP involving manufacturing/fabrication of the thermoelectric device and outsource the actual manufacturing/fabrication processes to the another entity.

All possible combinations of entities and third-parties are within the scope of the exemplary embodiments discussed herein.

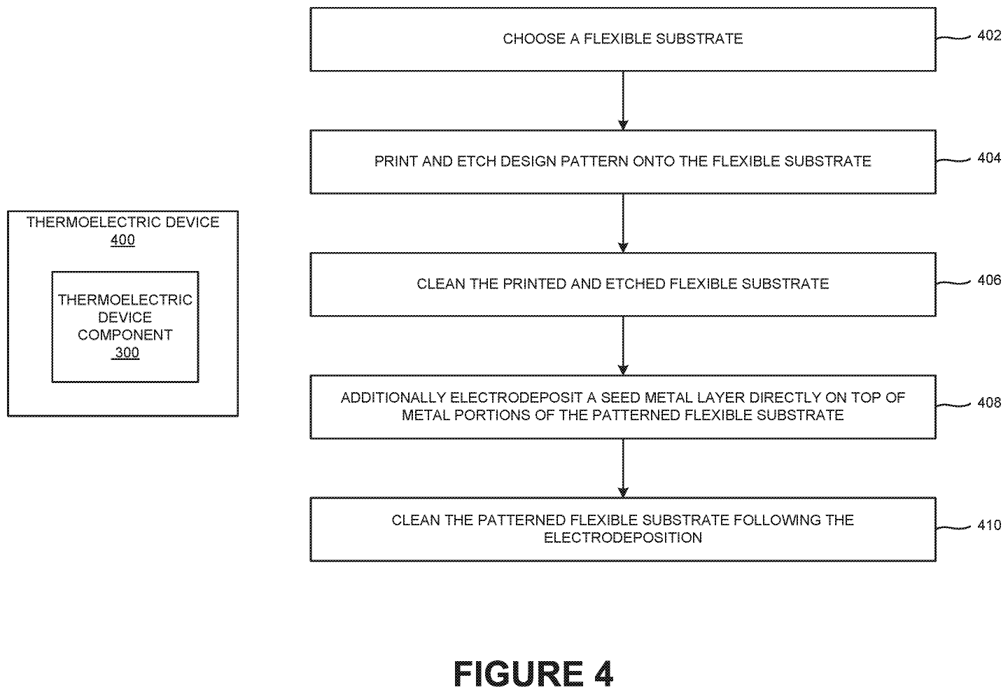

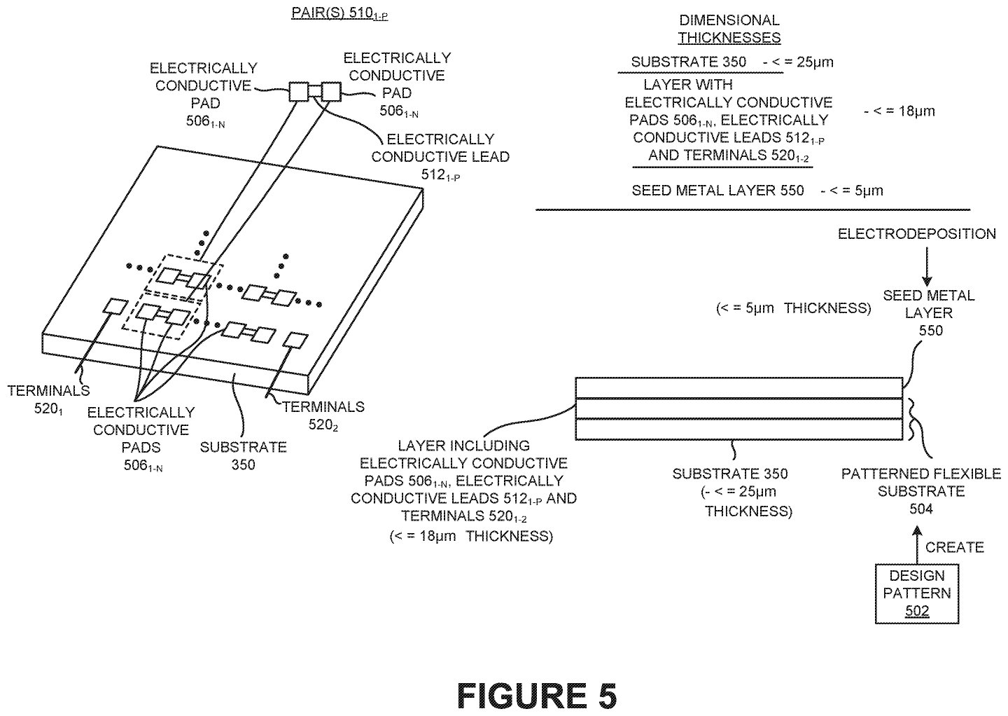

FIG. 4 shows the operations involved in realizing a patterned flexible substrate (e.g., patterned flexible substrate 504 shown in FIG. 5) of a thermoelectric device 400 as per a design pattern (e.g., design pattern 502 shown in FIG. 5), according to one or more embodiments. In one or more embodiments, operation 402 may involve choosing a flexible substrate (e.g., substrate 350) onto which, in operation 404, design pattern 502 may be printed (e.g., through inkjet printing, direct write, screen printing) and etched onto the flexible substrate. In one or more embodiments, a dimensional thickness of substrate 350 may be less than or equal to 25 μm.

Etching, as defined above, may refer to the process of removing (e.g., chemically) unwanted metal (say, Cu) from the patterned flexible substrate. In one example embodiment, a mask or a resist may be placed on portions of the patterned flexible substrate corresponding to portions of the metal that are to remain after the etch. Here, in one or more embodiments, the portions of the metal that remain on the patterned flexible substrate may be electrically conductive pads, electrically conductive leads and terminals formed on a surface of the patterned flexible substrate. FIG. 5 shows a patterned flexible substrate 504 including a number of electrically conductive pads 506_{1-N} formed thereon. Each electrically conductive pad 506_{1-N} may be a flat area of the metal that enables an electrical connection.

Also, FIG. 5 shows a majority set of the electrically conductive pads 506_{1-N} as including pairs 510_{1-P} of electrically conductive pads 506_{1-N} in which one electrically conductive pad 506_{1-N} may be electrically paired to another electrically conductive pad 506_{1-N} through an electrically conductive lead 512_{1-P} also formed on patterned flexible substrate 504; terminals 520₁₋₂ (e.g., analogous to terminals 370 and 372) may also be electrically conductive leads to measure the potential difference generated by the thermoelectric device/module fabricated based on design pattern 502. The aforementioned potential difference may be generated based on heat (or, cold) applied at an end of the thermoelectric device/module.

It should be noted that the configurations of the electrically conductive pads 506_{1-N}, electrically conductive leads 512_{1-P} and terminals 520₁₋₂ shown in FIG. 5 are merely for example purposes, and that other example configurations are within the scope of the exemplary embodiments discussed herein. It should also be noted that patterned flexible substrate 504 may be formed based on design pattern 502 in accordance with the printing and etching discussed above.

Example etching solutions employed may include but are not limited to ferric chloride and ammonium persulphate. Referring back to FIG. 4, operation 406 may involve cleaning the printed and etched flexible substrate. For example, acetone, hydrogen peroxide or alcohol may be employed therefor. Other forms of cleaning are within the scope of the exemplary embodiments discussed herein. In one or more embodiments, the aforementioned processes discussed in FIG. 4 may result in a dimensional thickness of electrically conductive pads 506_{1-N}, electrically conductive leads 512_{1-P} and terminals 520₁₋₂ being less than or equal to 18 μm.

The metal (e.g., Cu) finishes on the surface of patterned flexible substrate 504 may oxidize over time if left unprotected. As a result, in one or embodiments, operation 408 may involve additionally electrodepositing a seed metal layer 550 including Chromium (Cr), Nickel (Ni) and/or Gold (Au) directly on top of the metal portions (e.g., electrically conductive pads 506_{1-N}, electrically conductive leads 512_{1-P}, terminals 520₁₋₂) of patterned flexible substrate 504 following the printing, etching and cleaning. In one or more embodiments, a dimensional thickness of seed metal layer 550 may be less than or equal to 5 μm.

In one example embodiment, surface finishing may be employed to electrodeposit seed metal layer 550; the aforementioned surface finishing may involve Electroless Nickel Immersion Gold (ENIG) finishing. Here, a coating of two layers of metal may be provided over the metal (e.g., Cu) portions of patterned flexible substrate 504 by way of Au being plated over Ni. Ni may be the barrier layer between Cu and Au. Au may protect Ni from oxidization and may provide for low contact resistance. Other forms of surface finishing/electrodeposition may be within the scope of the exemplary embodiments discussed herein. It should be noted that seed metal layer 550 may facilitate contact of sputter deposited N-type thermoelectric legs (to be discussed below) and P-type thermoelectric legs (to be discussed below) thereto.

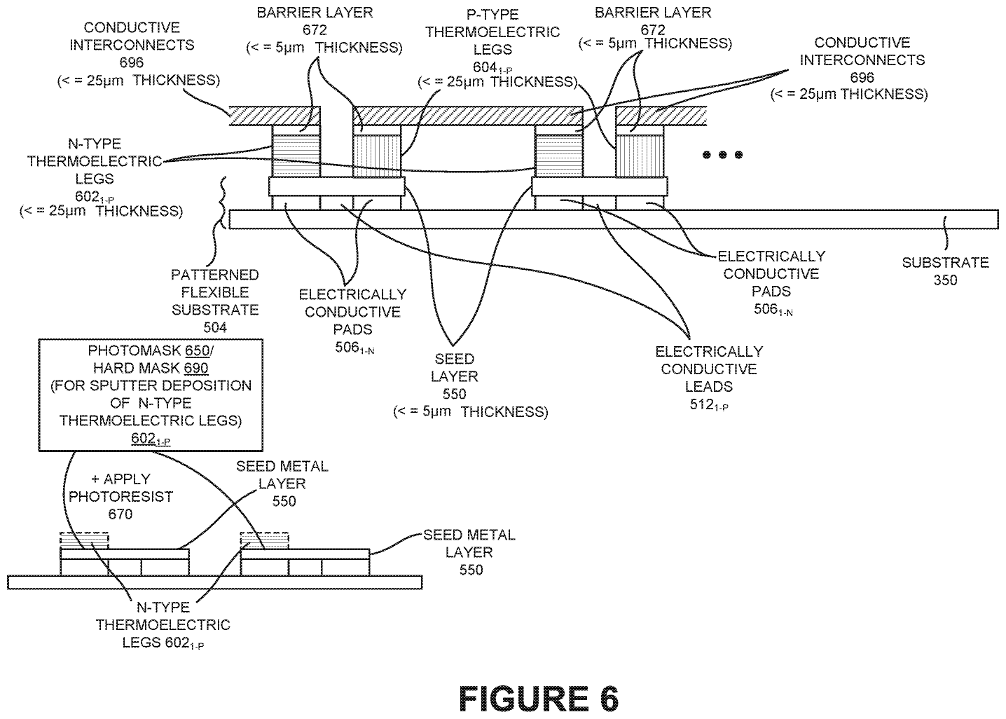

In one or more embodiments, operation 410 may then involve cleaning patterned flexible substrate 504 following the electrodeposition. FIG. 6 shows an N-type thermoelectric leg 602_{1-P} and a P-type thermoelectric leg 604_{1-P} formed on each pair 510_{1-P} of electrically conductive pads 506_{1-N}, according to one or more embodiments. In one or more embodiments, the aforementioned N-type thermoelectric legs 602_{1-P} and P-type thermoelectric legs 604_{1-P} may be formed on the surface finished patterned flexible substrate 504 (note: in FIG. 6, seed layer 550 is shown as surface finishing over electrically conductive pads 506_{1-N}/leads 512_{1-P}; terminals 520₁₋₂ have been omitted for the sake of clarity) of FIG. 5 through sputter deposition.

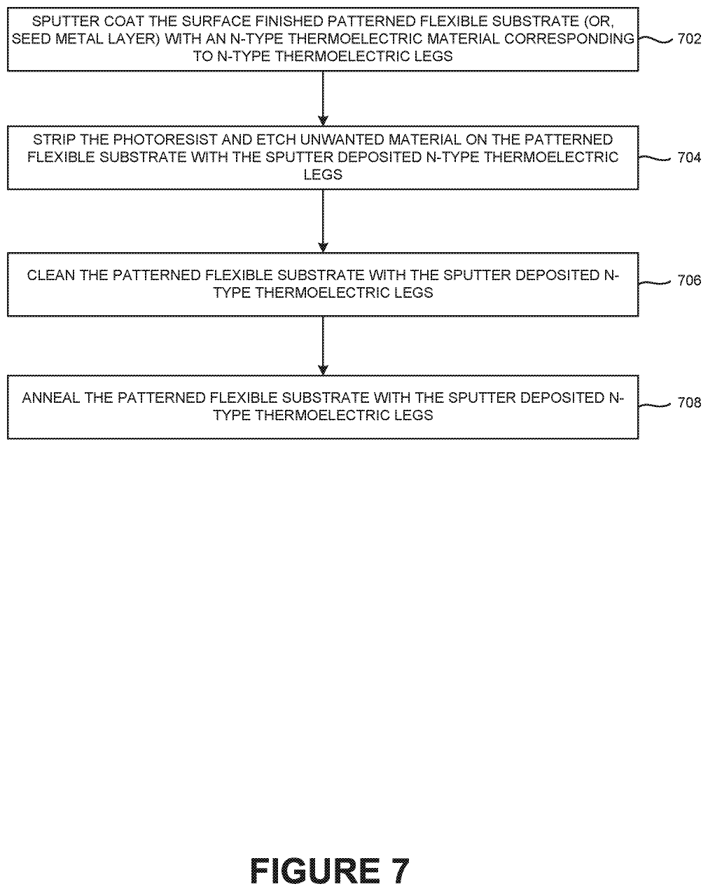

FIG. 7 details the operations involved in sputter deposition of N-type thermoelectric legs 602_{1-P} on the surface finished patterned flexible substrate 504 (or, seed metal layer 550) of FIG. 5, according to one or more embodiments. In one or more embodiments, the aforementioned process may involve a photomask 650 (shown in FIG. 6) on which patterns corresponding/complementary to the N-type thermoelectric legs 602_{1-P} may be generated. In one or more embodiments, a photoresist 670 (shown in FIG. 6) may be applied on the surface finished patterned flexible substrate 504, and photomask 650 placed thereon. In one or more embodiments, operation 702 may involve sputter coating (e.g., through magnetron sputtering) of the surface finished patterned flexible substrate 504 (or, seed metal layer 550) with an N-type thermoelectric material corresponding to N-type thermoelectric legs 602_{1-P}, aided by the use of photomask 650. The photoresist 670/photomask 650 functions are well understood to one skilled in the art; detailed discussion associated therewith has been skipped for the sake of convenience and brevity.

In one or more embodiments, operation 704 may involve stripping (e.g., using solvents such as dimethyl sulfoxide or alkaline solutions) of photoresist 670 and etching of unwanted material on patterned flexible substrate 504 with sputter deposited N-type thermoelectric legs 602_{1-P}. In one or more embodiments, operation 706 may involve cleaning the patterned flexible substrate 504 with the sputter deposited N-type thermoelectric legs 602_{1-P}; the cleaning process may be similar to the discussion with regard to FIG. 4.

In one or more embodiments, operation 708 may then involve annealing the patterned flexible substrate 504 with the sputter deposited N-type thermoelectric legs 602_{1-P}; the annealing process may be conducted (e.g., in air or vacuum) at 175° C. for 4 hours. In one or more embodiments, the annealing process may remove internal stresses and may contribute stability of the sputter deposited N-type thermoelectric legs 602_{1-P}. In one or more embodiments, a dimensional thickness of the sputter deposited N-type thermoelectric legs 602_{1-P} may be less than or equal to 25 μm.

It should be noted that P-type thermoelectric legs 604_{1-P} may also be sputter deposited on the surface finished pattern flexible substrate 504. The operations associated therewith are analogous to those related to the sputter deposition of N-type thermoelectric legs 602_{1-P}. Obviously, photomask 650 may have patterns corresponding/complementary to the P-type thermoelectric legs 604_{1-P} generated thereon. Detailed discussion associated with the sputter deposition of P-type thermoelectric legs 604_{1-P} has been skipped for the sake of convenience; it should be noted that a dimensional thickness of the sputter deposited P-type thermoelectric legs 604_{1-P} may also be less than or equal to 25 μm.

It should be noted that the sputter deposition of P-type thermoelectric legs 604_{1-P} on the surface finished patterned flexible substrate 504 may be performed after the sputter deposition of N-type thermoelectric legs 602_{1-P} thereon or vice versa. Also, it should be noted that various feasible forms of sputter deposition are within the scope of the exemplary embodiments discussed herein. In one or more embodiments, the sputter deposited P-type thermoelectric legs 604_{1-P} and/or N-type thermoelectric legs 602_{1-P} may include a material chosen from one of: Bismuth Telluride (Bi₂Te₃), Bismuth Selenide (Bi₂Se₃), Antimony Telluride (Sb₂Te₃), Lead Telluride (PbTe), Silicides, Skutterudites and Oxides.

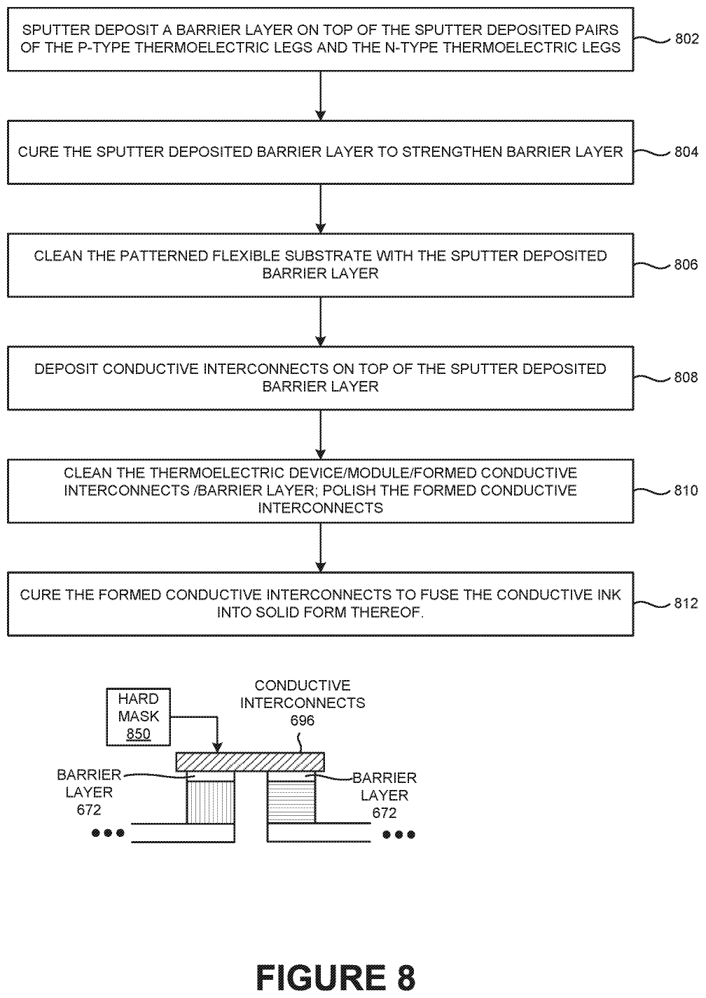

FIG. 8 details operations involved in deposition of a barrier layer 672 (refer to FIG. 6) on top of the sputter deposited pairs of P-type thermoelectric legs 604_{1-P} and N-type thermoelectric legs 602_{1-P} and forming conductive interconnects 696 on top of barrier layer 672, according to one or more embodiments.

In one or more embodiments, operation 802 may involve sputter depositing barrier layer 672 (e.g., film) on top of the sputter deposited pairs of the P-type thermoelectric legs 604_{1-P} and the N-type thermoelectric leg 602_{1-P} discussed above. In one or more embodiments, barrier layer 672 may be electrically conductive and may have a higher melting temperature than the thermoelectric material forming the P-type thermoelectric legs 604_{1-P} and the N-type thermoelectric legs 602_{1-P}. In one or more embodiments, barrier layer 672 may prevent corruption (e.g., through diffusion, sublimation) of one layer (e.g., the thermoelectric layer including the P-type thermoelectric legs 604_{1-P} and the N-type thermoelectric legs 602_{1-P}) by another layer. An example material employed as barrier layer 672 may include but is not limited to Cr, Ni or Au. Further, in one or more embodiments, barrier layer 672 may further aid metallization contact therewith (e.g., with conductive interconnects 696).

In one or more embodiments, a dimensional thickness of barrier layer 672 may be less than or equal to 5 μm. It is obvious that another photomask (not shown) analogous to photomask 650 may be employed to aid the patterned sputter deposition of barrier layer 672; details thereof have been skipped for the sake of convenience and clarity. In one or more embodiments, operation 804 may involve may involve curing barrier layer 672 at 175° C. for 4 hours to strengthen barrier layer 672. In one or more embodiments, operation 806 may then involve cleaning patterned flexible substrate 504 with barrier layer 672.

In one or more embodiments, operation 808 may involve depositing conductive interconnects 696 on top of barrier layer 672. In one example embodiment, the aforementioned deposition may be accomplished by screen printing silver (Ag; Ag nano-ink) ink or other conductive forms of ink on barrier layer 672. Other forms of conductive interconnects 696 based on conductive paste(s) are within the scope of the exemplary embodiments discussed herein. As shown in FIG. 8, a hard mask 850 may be employed to assist the selective application of conductive interconnects 696 based on screen printing of Ag ink. In one example embodiment, hard mask 850 may be a stencil.

In one or more embodiments, the screen printing of Ag ink may contribute to the continued flexibility of the thermoelectric device/module and low contact resistance. In one or more embodiments, operation 810 may involve cleaning (e.g., using one or more of the processes discussed above) the thermoelectric device/module/formed conductive interconnects 696/barrier layer 672 and polishing conductive interconnects 696. In one example embodiment, the polishing may be followed by another cleaning process. In one or more embodiments, operation 812 may then involve curing conductive interconnects 696 at 175° C. for 4 hours to fuse the conductive ink into solid form thereof. In one or more embodiments, conductive interconnects 696 may have a dimensional thickness less than or equal to 25 μm.

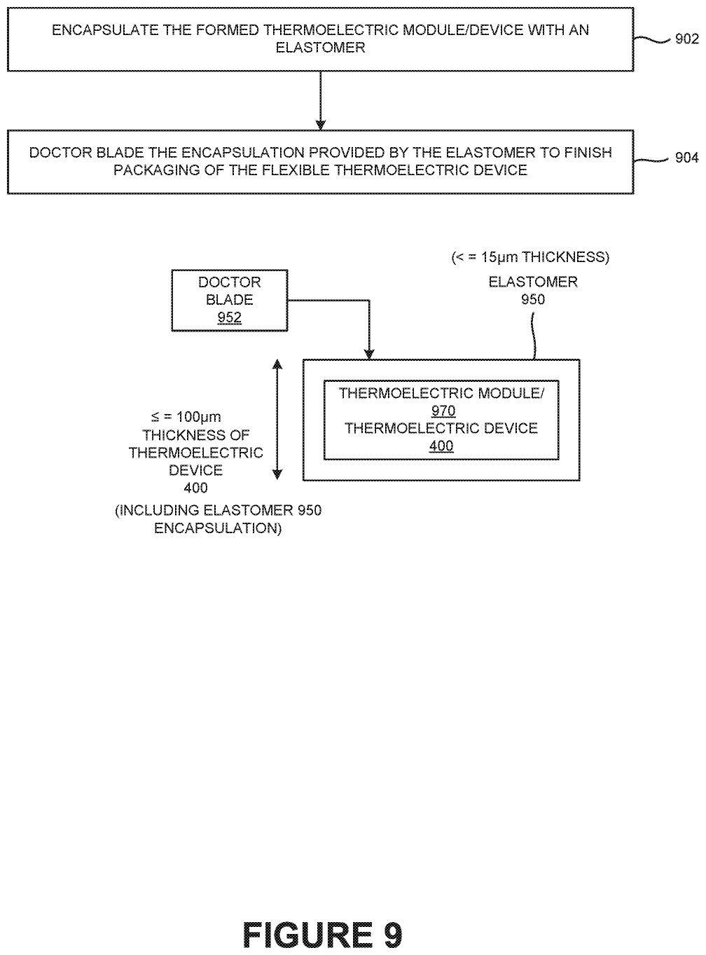

FIG. 9 details the operations involved in encapsulating the thermoelectric device (e.g., thermoelectric module 970)/module discussed above, according to one or more embodiments. In one or more embodiments, operation 902 may involve encapsulating the formed thermoelectric module (e.g., thermoelectric module 970)/device (with barrier layer 672 and conductive interconnects 696) with an elastomer 950 to render flexibility thereto. In one or more embodiments, as shown in FIG. 9, the encapsulation provided by elastomer 950 may have a dimensional thickness of less than or equal to 15 μm. In one or more embodiments, operation 904 may involve doctor blading (e.g., using doctor blade 952) the encapsulation provided by elastomer 950 to finish packaging of the flexible thermoelectric device/module discussed above.

In one or more embodiments, the doctor blading may involve controlling precision of a thickness of the encapsulation provided by elastomer 950 through doctor blade 952. In one example embodiment, elastomer 950 may be silicone. Here, said silicone may be loaded with nano-size aluminum oxide (Al₂O₃) powder to enhance thermal conductivity thereof to aid heat transfer across the thermoelectric module.

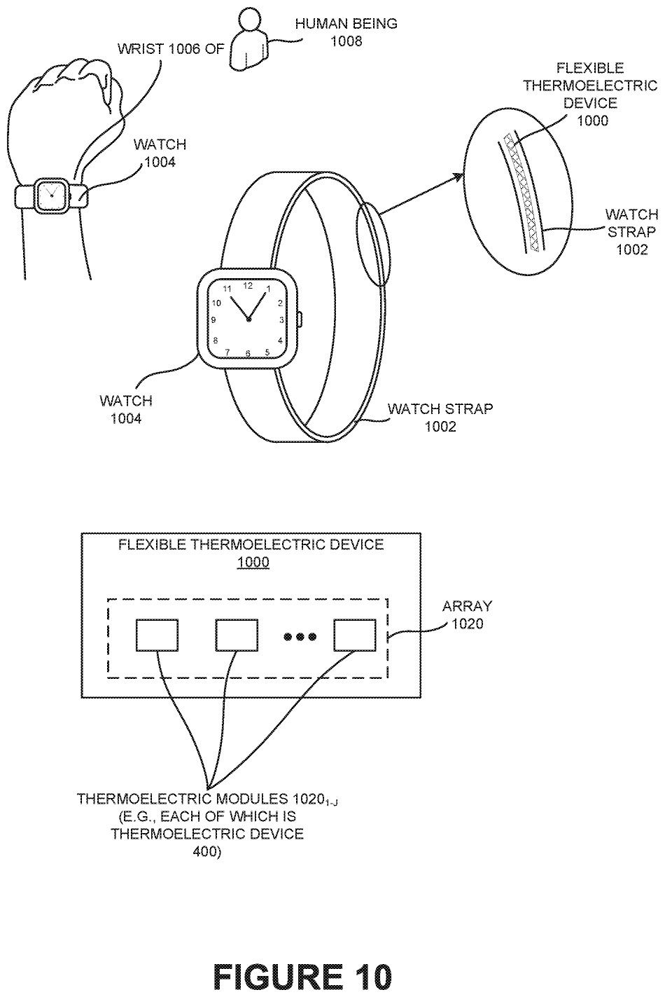

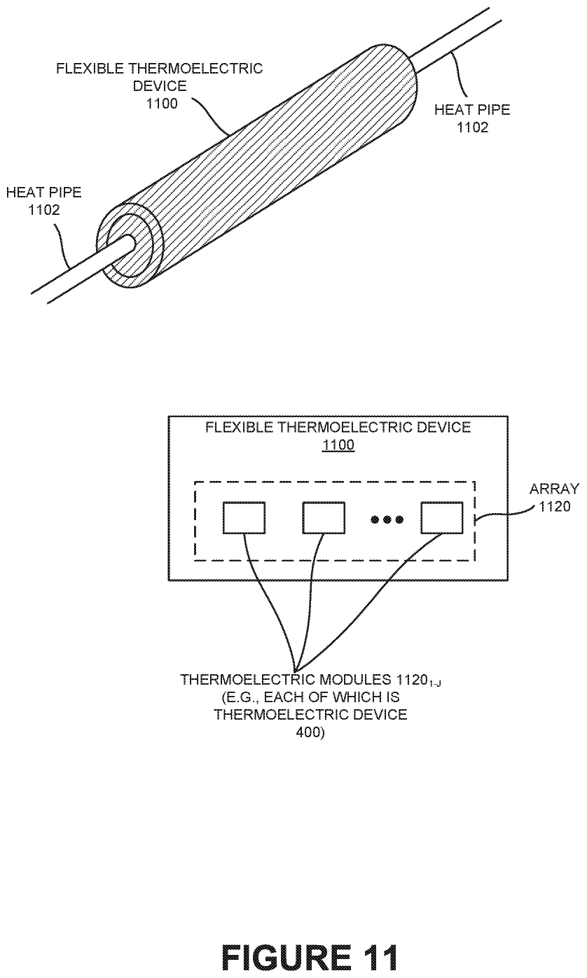

In one or more embodiments, as seen above, all operations involved in fabricating the thermoelectric device/module (e.g., thermoelectric device 400) render said thermoelectric device/module flexible. FIG. 10 shows a flexible thermoelectric device 1000 discussed herein embedded within a watch strap 1002 of a watch 1004 completely wrappable around a wrist 1006 of a human being 1008; flexible thermoelectric device 1000 may include an array 1020 of thermoelectric modules 1020_{1-J} (e.g., each of which is thermoelectric device 400) discussed herein. In one example embodiment, flexible thermoelectric device 1000 may serve to augment or substitute power derivation from a battery of watch 1004. FIG. 11 shows a flexible thermoelectric device 1100 discussed herein wrapped around a heat pipe 1102; again, flexible thermoelectric device 1100 may include an array 1120 of thermoelectric modules 1120_{1-J} (e.g., each of which is thermoelectric device 400) discussed herein. In one example embodiment, flexible thermoelectric device 1100 may be employed to derive thermoelectric power (e.g., through array 1120) from waste heat from heat pipe 1102.

It should be noted that although photomask 650 is discussed above with regard to deposition of N-type thermoelectric legs 602_{1-P} and a P-type thermoelectric legs 604_{1-P}, the aforementioned deposition may, in one or more other embodiments, involve a hard mask 690, as shown in FIG. 6. Further, it should be noted that flexible thermoelectric device 400/1000/1100 may be fabricated/manufactured such that the aforementioned device is completely wrappable and bendable around a system element (e.g., watch 1004, heat pipe 1102) that requires said flexible thermoelectric device 400/1000/1100 to perform a thermoelectric power generation function using the system element.

The abovementioned flexibility of thermoelectric device 400/1000/1100 may be enabled through proper selection of flexible substrates (e.g., substrate 350) and manufacturing techniques/processes that aid therein, as discussed above. Further, flexible thermoelectric device 1000/1100 may be bendable 360° such that the entire device may completely wrap around the system element discussed above. Still further, in one or more embodiments, an entire dimensional thickness of the flexible thermoelectric module (e.g., flexible thermoelectric device 400) in a packaged form may be less than or equal to 100 μm, as shown in FIG. 9.

Last but not the least, as the dimensions involved herein are restricted to less than or equal to 100 μm, the flexible thermoelectric device/module discussed above may be regarded as being thin-film based (e.g., including processes involved in fabrication thereof).

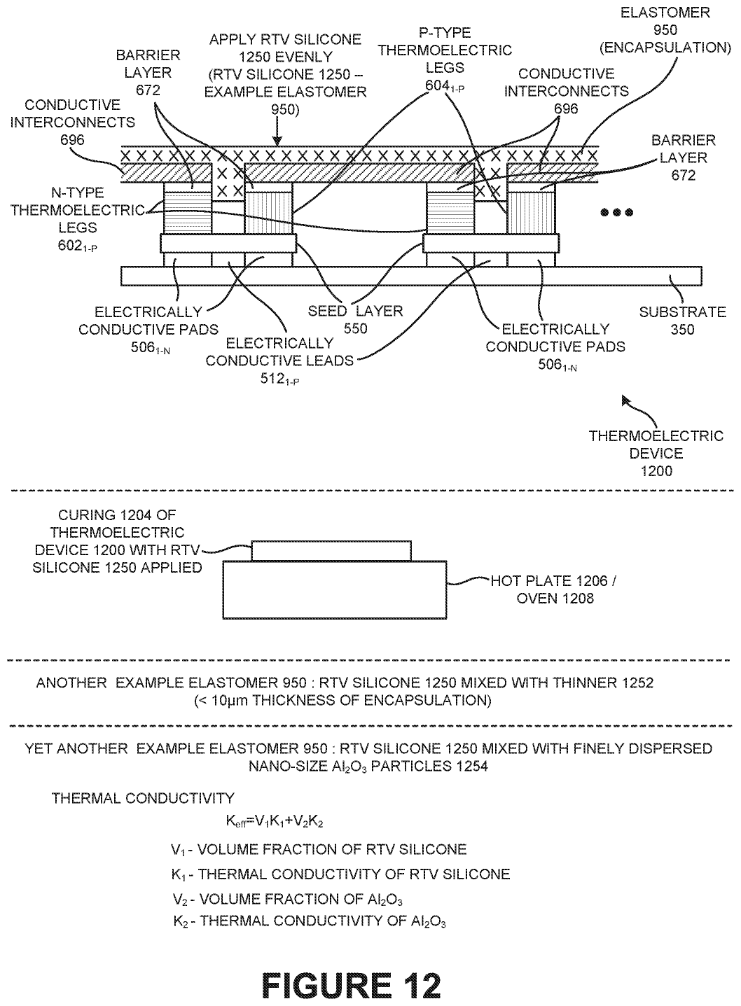

FIG. 12 shows a thermoelectric device 1200 (e.g., thermoelectric module 970, also refer to the thermoelectric device of FIG. 6) discussed herein with elastomer encapsulation, according to one or more embodiments. In one or more embodiments, elastomer 950 may be provided on top of conductive interconnects 696; in certain embodiments, the encapsulation provided through elastomer 950 may extend into physical spaces between adjacent N-type thermoelectric legs 602_{1-P} and P-type thermoelectric legs 604_{1-P} in a direction perpendicular to a plane of substrate 350.

FIG. 12 also shows Room Temperature Vulcanizing (RTV) silicone 1250 (example elastomer 950) applied evenly across a surface of the thermoelectric device of FIG. 6, according to one or more embodiments. In one or more embodiments, as conductive interconnects 696 may be discontinuous and/or the adjacent N-type thermoelectric legs 602_{1-P} and P-type thermoelectric legs 604_{1-P} may have physical spaces therebetween, one or more hard mask(s) 1202 (e.g., one or more stencil(s)) with patterns corresponding to the thermoelectric device of FIG. 6 and the desired configuration of the encapsulation may be employed, as shown in FIG. 12, to apply said RTV silicone 1250 evenly across the surface of the thermoelectric device.

In one or more embodiments, following the application of RTV silicone 1250, thermoelectric device 1200/RTV silicone 1250 may be cured (e.g., curing 1204 on a hot plate 1206 or an oven 1208) at 150° C. to strengthen the formed layer, as shown in FIG. 12. In one or more other embodiments, RTV silicone 1250 may be mixed with a thinner 1252 (e.g., silicone fluid; other examples are within the scope of the exemplary embodiments discussed herein) to enable the resulting mixture to provide for a less than 10 μm thickness of the formed encapsulation layer (in general, as discussed above, the encapsulation layer may be less than or equal to 15 μm in thickness). It should be noted that the encapsulation may not solely be based on the doctor blading discussed above. Other methods to accomplish the encapsulation such as spin coating are within the scope of the exemplary embodiments discussed herein.

FIG. 12 also shows RTV silicone 1250 mixed with finely dispersed nano-sized Alumina (Al₂O₃) particles 1254 to improve thermal conductivity thereof, as discussed above, according to one or more embodiments. Thermal conductivity of RTV silicone may be ˜0.14 Watts per meter Kelvin (W/mK) at room temperature (e.g., 25° C.), and thermal conductivity of Al₂O₃ may be ˜18 W/mK at room temperature. In one or more embodiments, the thermal conductivity of a resultant mixture of RTV silicone and the Al₂O₃ particles may be expressed in terms of volume ratios of RTV silicone and Al₂O₃ as:

K_{eff}=V₁K₁+V₂K₂,

where V₁ is the volume fraction of RTV silicone, V₂ is the volume fraction of Al₂O₃ (finely dispersed nano-sized particles), K₁ is the thermal conductivity of RTV silicone, K₂ is the thermal conductivity of Al₂O₃, and K_{eff} is the effective thermal conductivity of the resultant mixture.

As an example, if 5% of Al₂O₃ is solid loaded into RTV silicone rubber, V₁ is 0.95 and V₂ is 0.05. K₁ here is 0.14 and K₂ is 18.

K_{eff}=0.95×0.14+0.05×18=1.033W/mK

In another example, if 10% of Al₂O₃ is solid loaded into the RTV silicone rubber, V₁ is 0.9 and V₂ is 0.1.

K_{eff}=0.9×0.14+0.1×18=1.926W/mK

It is obvious that it may be advantageous to use filler material (e.g., Al₂O₃) of a higher thermal conductivity and/or a higher volume fraction to drastically improve thermal conductivity of the resultant mixture of RTV silicone and said filler material without sacrificing the desired final thickness (e.g., the thinner the better) of the encapsulation. Also, it is obvious that elastomer 950 may not solely be limited to RTV silicone 1250. Varieties of market ready high thermally conductive materials (e.g., filler material) and elastomers (or rubber) may be available for use in thermoelectric device 1200 and, therefore, are within the scope of the exemplary embodiments discussed herein. Preferred embodiments may involve the use of a mixture of RTV silicone rubber and Al₂O₃ nano-powder for encapsulation purposes.

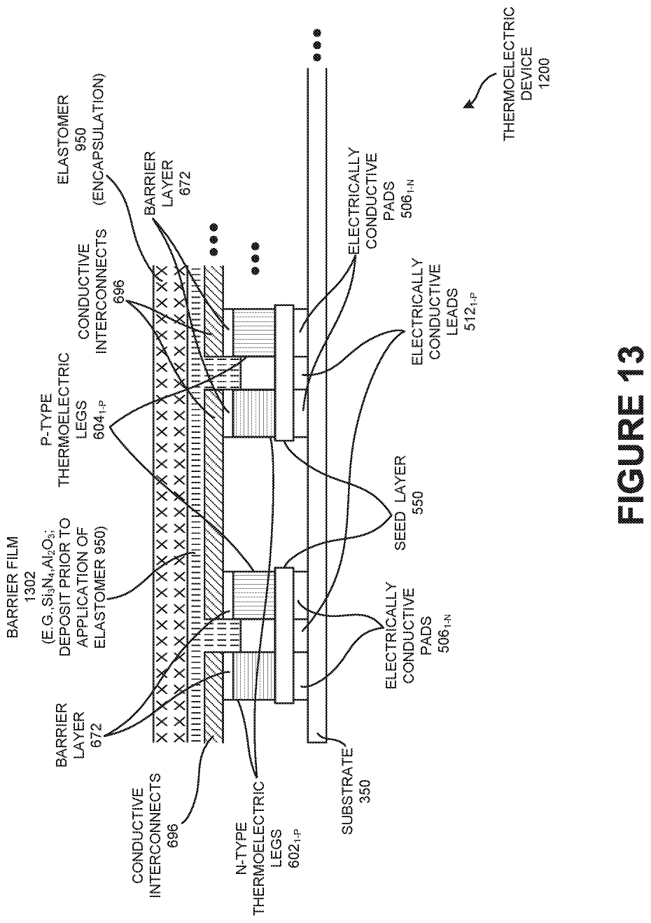

FIG. 13 shows deposition (e.g., through sputtering) of a barrier film 1302 (e.g., of Silicon Nitride (Si₃N₄), of Alumina (Al₂O₃)) prior to application of elastomer 950 (e.g., RTV silicone, an elastomer with thinner, an elastomer with filler material) to encapsulate thermoelectric device 1200, according to one or more embodiments. In one or more embodiments, barrier film 1302 may be deposited (e.g., on top of conductive interconnects 696) to reduce moisture/water vapor/oxygen pervasion into layers of thermoelectric device 1200. It is obvious that moisture barrier thin-films (e.g., barrier film 1302) other than those including Si₃N₄ and/or Al₂O₃ may be employed in thermoelectric device 1200 prior to encapsulation thereof.

In one or more embodiments, a photomask or a hard mask (e.g., analogous to photo mask 650/hard mask 850) with patterns corresponding to barrier film 1302/elastomer 950 may be employed in the abovementioned deposition of barrier film 1302. In one example implementation, a 1-2 μm Si₃N₄ film may be sputter deposited to provide hermetic sealing to the thermoelectric layers of thermoelectric device 1200 for passivation purposes; then, RTV silicone rubber material (example elastomer 950) may be placed evenly thereon (e.g., based on doctor blading) to encapsulate thermoelectric device 1200; for example, the RTV silicone rubber material may be provided/placed around the Si₃N₄ film. The encapsulated thermoelectric device 1200/example elastomer 950 may then be cured at 150° C. for a couple of hours to cross-link polymers therein and to provide sealing.

It should be noted that the exemplary embodiments discussed herein provide for encapsulating the thin-film flexible thermoelectric device 1200 into a state of permanent sealing; only output pads may be exposed. As discussed above, the encapsulation may be less than or equal to 15 μm in thickness (in one embodiment, the encapsulation may be less than 10 μm in thickness). The abovementioned process of encapsulation, in conjunction with other processes involved in fabrication/manufacturing of thermoelectric device 400/thermoelectric module 970/thermoelectric device 1200, may enable said device to stretch or bend based on the flexibility of the final product discussed above.

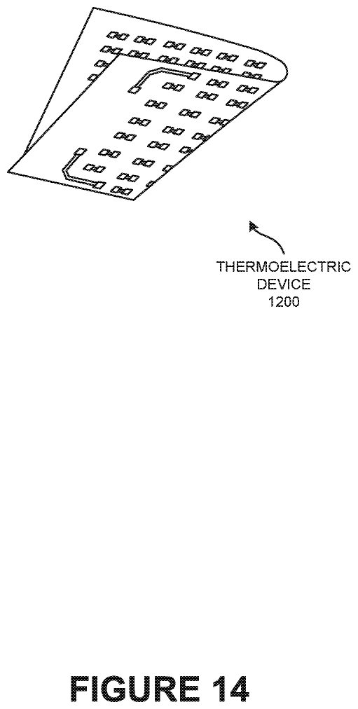

FIG. 14 shows flexibility and bendability of an example thermoelectric device 1200 manufactured in accordance with the processes discussed herein. The aforementioned flexibility and bendability may facilitate use of the example thermoelectric device 1200 in a variety of applications, some of which are discussed with reference to FIGS. 10-11.

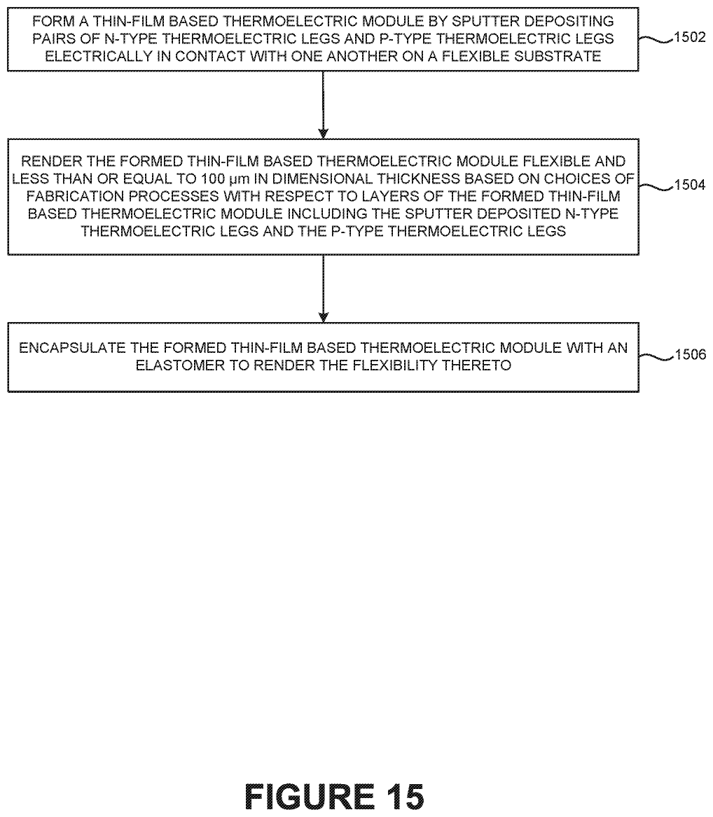

FIG. 15 shows a process flow diagram detailing the operations involved in flexibly encapsulating a flexible thin-film based thermoelectric module (e.g., thermoelectric device 1200) with a sputter deposited layer of N-type (e.g., N-type thermoelectric legs 602_{1-P}) and P-type (e.g., P-type thermoelectric legs 604_{1-P}) thermoelectric legs, according to one or more embodiments.

In one or more embodiments, operation 1502 may involve forming the thin-film based thermoelectric module by sputter depositing pairs of N-type thermoelectric legs and P-type thermoelectric legs electrically in contact with one another on a flexible substrate (e.g., substrate 350). In one or more embodiments, the flexible substrate may be Al foil, a sheet of paper, teflon, plastic, a single-sided Cu clad laminate sheet, or a double-sided Cu clad laminate sheet, and may have a dimensional thickness less than or equal to 25 μm.

In one or more embodiments, operation 1504 may involve rendering the formed thin-film based thermoelectric module flexible and less than or equal to 100 μm in dimensional thickness based on choices of fabrication processes with respect to layers of the formed thin-film based thermoelectric module including the sputter deposited N-type thermoelectric legs and the P-type thermoelectric legs. In one or more embodiments, operation 1506 may then involve encapsulating the formed thin-film based thermoelectric module with an elastomer (e.g., elastomer 950) to render the flexibility thereto.

In one or more embodiments, the elastomer encapsulation may have a dimensional thickness less than or equal to 15 μm. In one or more embodiments, the flexibility may enable an array (e.g., array 1020/1120) of thin-film based thermoelectric modules, each of which is equivalent to the thin-film based thermoelectric module formed on the flexible substrate with the elastomer encapsulation, to be completely wrappable and bendable around a system element from which the array of the thin-film based thermoelectric modules is configured to derive thermoelectric power.

In one or more embodiments, a layer of the formed thin-film based thermoelectric module including the sputter deposited N-type thermoelectric legs and the P-type thermoelectric legs may have a dimensional thickness less than or equal to 25 μm.

As seen above, exemplary embodiments may offer a flexible thin-film based thermoelectric solution that is scalable with respect to a variety of applications. Below is a discussion related to a preferred embodiment of the flexibly encapsulated thermoelectric device 1200. Support for the preferred embodiment may be found, for example, in the parent applications included in the CLAIM OF PRIORITY section above.

In one or more embodiments, the flexible substrate may be a metal clad laminate in the form of a sheet. As discussed above, the aforementioned flexible substrate may be a single-sided or a double-sided metal (e.g., Cu) clad laminate. As shown in FIG. 3, the material for substrate 350 may be a metal clad laminate available in the market in a rolled form thereof and amenable to roll-to-roll processing. A sheet of the thicknesses discussed above and/or a commercially available version thereof may be procured in the rolled form and then straightened out. As seen above, electrically conductive pads 506_{1-N}, electrically conductive leads 512_{1-P} and terminals (e.g., terminals 372) may be etched out of a metal cladding (e.g., Cu) of the metal clad laminate. An example implementation of the metal clad laminate is Kapton® with Cu on one surface or both surfaces. Thermoelectric legs (e.g., N-type thermoelectric legs 602_{1-P}) and P-type thermoelectric legs (e.g., P-type thermoelectric legs 604_{1-P}) discussed above may not be directly deposited on the metal clad laminate. As discussed above, the metal clad laminate (example of substrate 350) in the rolled form may be straightened out, followed by the etching and patterning process of the metal cladding to form electrically conductive pads 506_{1-N}, electrically conductive leads 512_{1-P} and the terminals (e.g., terminals 372). The aforementioned patterning process may then be followed by finishing at a Printed Circuit Board (PCB) housing with industrial processes implemented at scale (e.g., meters of the laminate sheet roll-to-roll). The aforementioned etched electrically conductive pads 506_{1-N} and electrically conductive leads 512_{1-P} (and, terminals 372) may form a bottom metal layer.

In one or more preferred embodiments, the stack or the thermoelectric layer including N-type thermoelectric legs 602_{1-P} and P-type thermoelectric legs 604_{1-P} may include Bismuth (Bi), Antimony (Sb) and/or Tellurium (Te) that are widely used in the industry; however, the composition and stoichiometry thereof may be proprietary. In a standard implementation, the etched metal (e.g., Cu) cladding may be finished with Gold (Au) at a PCB vendor utilizing specific processes and tools.

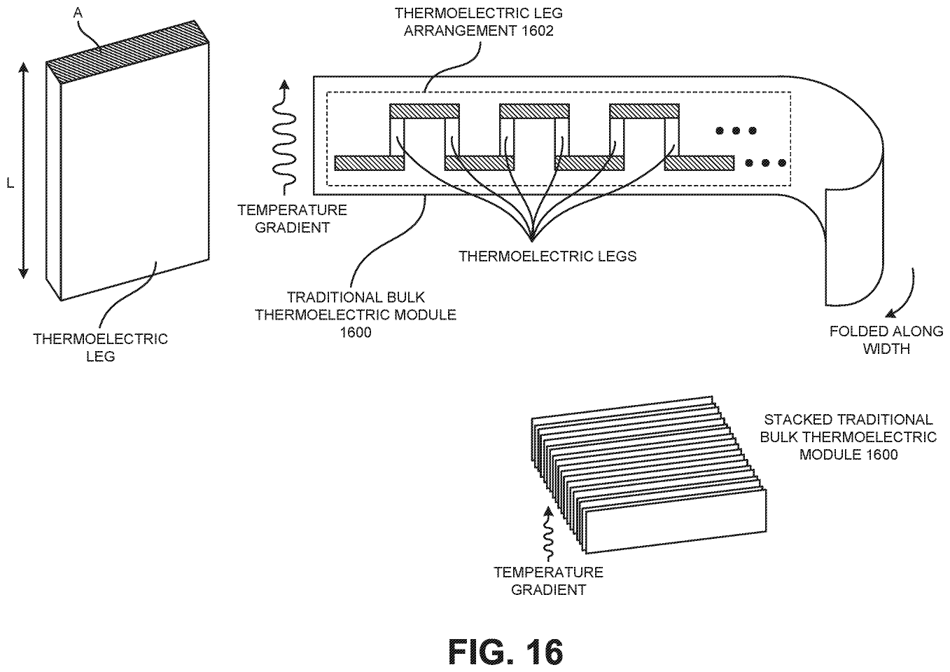

In a typical bulk thermoelectric module, the thermoelectric legs are completely different from those of the exemplary embodiments discussed herein. Typically, the legs may be longer with smaller cross-sectional area. For example, the length (L) divided by the cross-sectional area (A), or, L/A may be 20 or higher. If the width (W) and height (H) of the thermoelectric legs are 1 mm each, then L may be ˜20 mm. FIG. 16 shows a typical thermoelectric leg arrangement 1602 in a traditional bulk thermoelectric module 1600. Here, the temperature gradient (or, heat transfer) may be across L from top to bottom of traditional bulk thermoelectric module 1600. In order for the heat transfer to be utilized efficiently, traditional bulk thermoelectric module 1600 may have to be folded along the width of a strip thereof. FIG. 16 shows traditional bulk thermoelectric module 1600 folded as strips on top of one another.

In exemplary embodiments discussed herein, the temperature gradient (or, heat transfer) may be along a direction perpendicular to a plane of a surface of substrate 350/the metal clad laminate, as indicated by and implied through FIGS. 2-6. In case of traditional bulk thermoelectric module 1600, the heat transfer may be along the plane of the surface of the structure/substrate thereof. In an example implementation of the embodiments discussed herein, each N-type thermoelectric leg 602_{1-P} and P-type thermoelectric leg 604_{1-P} may be of dimensions 0.5 mm×0.5 mm×20 microns. Thus, L/A may be ˜0.08. Because the power produced may be proportional to a number of thermocouples and L/A, exemplary embodiments may require at least 250 cells (20/0.08) to have comparable performance to traditional bulk thermoelectric module 1600.

However, in one or more embodiments, exemplary embodiments discussed herein (e.g., thermoelectric device 400/thermoelectric module 970) may be paper thin with an area in the range of a square meter and above. This enables the distribution of a number (e.g., thousands to millions) of N-type thermoelectric legs 602_{1-P} and P-type thermoelectric legs 604_{1-P} across substrate 350 with an area in the range of a square meter and above. This number can easily exceed 250, thereby easily exceeding performance of traditional bulk thermoelectric module 160. In the case of wrapping thermoelectric device 400/thermoelectric module 970 around irregular, dynamic (e.g., human body part such as a wrist) and curved surfaces (e.g., pipes), it is the temperature gradient perpendicular to the plane of surface of substrate 350 and the flexibility of thermoelectric device 400/thermoelectric module 970 that enable heat from the irregular, dynamic and curved surfaces to be leveraged. In the case of traditional bulk thermoelectric module 1600, even the flexibility of an analogous substrate/substrate may be useless because the temperature gradient/heat transfer therein may be along the surface of the structure parallel thereto.

In traditional bulk thermoelectric module 1600, all N-type and P-type thermoelectric legs may not be connected following deposition thereof. In contrast, exemplary embodiments discussed herein may involve depositing conductive interconnects 696 on top of N-type thermoelectric legs 602_{1-P} and P-type thermoelectric legs 604_{1-P}. to connect all pairs 510_{1-P} to one another. In one or more embodiments, as discussed above, this may be accomplished through deposition of barrier layer 672 directly on top of the N-type thermoelectric legs 602_{1-P} and the P-type thermoelectric legs 604_{1-P}, and then forming conductive interconnects 696 on top of barrier layer 672. The aforementioned formation of conductive interconnects 696 may be through utilizing Ag (e.g., in nano-ink form) printing (e.g., through screen printing and/or doctor blading). Other forms of conductive ink are within the scope of the exemplary embodiments discussed herein.

In one or more embodiments, barrier layer 672 may be employed to control thin-film resistance prior to the metallization through conductive interconnects 696. In one or more embodiments, this may be critical because substrate 350 may have millions of legs thereacross, which warrants keeping overall resistances low. In one or more embodiments, this may be accomplished by depositing thin film Cr/Ni/Au layers (or, barrier layer 672) prior to the screen printing of Ag as conductive interconnects 696.

Although the present embodiments have been described with reference to specific example embodiments, it will be evident that various modifications and changes may be made to these embodiments without departing from the broader spirit and scope of the various embodiments. Accordingly, the specification and drawings are to be regarded in an illustrative rather than a restrictive sense.

What is claimed is:

1. A method of a thermoelectric module, comprising:
straightening out a metal clad laminate previously in a rolled sheet form thereof;
etching and patterning a metal cladding of the metal clad laminate to form electrically conductive pads, leads and terminals therewith across a surface of the metal clad laminate following the straightening;
sputter depositing a plurality of pairs of N-type thermoelectric legs and P-type thermoelectric legs electrically in contact with one another on top of the formed electrically conductive pads across the surface of the metal clad laminate, with each electrically conductive lead establishing electrical contact between a pair of electrically conductive pads;
sputter depositing a barrier metal layer on top of the plurality of pairs of the N-type thermoelectric legs and the P-type thermoelectric legs to further aid metallization contact therewith;
depositing conductive interconnects directly on top of the sputter deposited barrier metal layer to connect all of the plurality of pairs of the N-type thermoelectric legs and the P-type thermoelectric legs to one another to form the thermoelectric module; and
utilizing a temperature gradient perpendicular to a plane of the surface of the metal clad laminate of the formed thermoelectric module to derive thermoelectric power from a system element.

2. The method of claim 1, comprising one of: Chromium (Cr), Nickel (Ni) and Gold (Au) being the barrier metal layer.

3. The method of claim 1, further comprising depositing the conductive interconnects through at least one of: screen printing conductive forms of ink on the sputter deposited barrier metal layer and doctor blading thereof.

4. The method of claim 1, further comprising encapsulating the formed thermoelectric module with an elastomer to render flexibility thereto.

5. The method of claim 4, comprising encapsulating the formed thermoelectric module with one of: Room-Temperature-Vulcanizing (RTV) silicone and a mixture of RTV silicone and a thinner as the elastomer.

6. The method of claim 4, comprising encapsulating the formed thermoelectric module with the elastomer based on one of: doctor blading and spin coating.

7. The method of claim 4, further comprising mixing RTV silicone with finely dispersed finely dispersed nano-sized Alumina (Al₂O₃) particles as the elastomer to improve thermal conductivity thereof in accordance with the elastomer having an effective thermal conductivity K_{eff}=V₁K₁+V₂K₂,
wherein V₁ is the volume fraction of the RTV silicone, V₂ is the volume fraction of the finely dispersed nano-sized Al₂O₃ particles, K₁ is the thermal conductivity of the RTV silicone, and K₂ is the thermal conductivity of Al₂O₃.

8. The method of claim 4, further comprising:
depositing a moisture barrier thin film on the formed thermoelectric module prior to encapsulation thereof with the elastomer; and
providing the encapsulation through the elastomer around the deposited moisture barrier thin film.

9. A method of a thermoelectric module, comprising:
straightening out a metal clad laminate previously in a rolled sheet form thereof;
etching and patterning a metal cladding of the metal clad laminate to form electrically conductive pads, leads and terminals therewith across a surface of the metal clad laminate following the straightening;
sputter depositing a plurality of pairs of N-type thermoelectric legs and P-type thermoelectric legs electrically in contact with one another on top of the formed electrically conductive pads across the surface of the metal clad laminate, with each electrically conductive lead establishing electrical contact between a pair of electrically conductive pads;
sputter depositing a barrier metal layer comprising one of: Cr, Ni and Au on top of the plurality of pairs of the N-type thermoelectric legs and the P-type thermoelectric legs to further aid metallization contact therewith;
depositing conductive interconnects directly on top of the sputter deposited barrier metal layer to connect all of the plurality of pairs of the N-type thermoelectric legs and the P-type thermoelectric legs to one another to form the thermoelectric module; and
utilizing a temperature gradient perpendicular to a plane of the surface of the metal clad laminate of the formed thermoelectric module to derive thermoelectric power from a system element.

10. The method of claim 9, further comprising depositing the conductive interconnects through at least one of: screen printing conductive forms of ink on the sputter deposited barrier metal layer and doctor blading thereof.

11. The method of claim 9, further comprising encapsulating the formed thermoelectric module with an elastomer to render flexibility thereto.

12. The method of claim 11, comprising encapsulating the formed thermoelectric module with one of: Room-Temperature-Vulcanizing (RTV) silicone and a mixture of RTV silicone and a thinner as the elastomer.

13. The method of claim 11, comprising encapsulating the formed thermoelectric module with the elastomer based on one of: doctor blading and spin coating.

14. The method of claim 11, further comprising mixing RTV silicone with finely dispersed finely dispersed nano-sized Alumina (Al₂O₃) particles as the elastomer to improve thermal conductivity thereof in accordance with the elastomer having an effective thermal conductivity K_{eff}=V₁K₁+V₂K₂,
wherein V₁ is the volume fraction of the RTV silicone, V₂ is the volume fraction of the finely dispersed nano-sized Al₂O₃ particles, K₁ is the thermal conductivity of the RTV silicone, and K₂ is the thermal conductivity of Al₂O₃.

15. The method of claim 11, further comprising:
depositing a moisture barrier thin film on the formed thermoelectric module prior to encapsulation thereof with the elastomer; and
providing the encapsulation through the elastomer around the deposited moisture barrier thin film.

16. A method of a thermoelectric module, comprising:
straightening out a metal clad laminate previously in a rolled sheet form thereof;
etching and patterning a metal cladding of the metal clad laminate to form electrically conductive pads, leads and terminals therewith across a surface of the metal clad laminate following the straightening;
sputter depositing a plurality of pairs of N-type thermoelectric legs and P-type thermoelectric legs electrically in contact with one another on top of the formed electrically conductive pads across the surface of the metal clad laminate, with each electrically conductive lead establishing electrical contact between a pair of electrically conductive pads;
sputter depositing a barrier metal layer on top of the plurality of pairs of the N-type thermoelectric legs and the P-type thermoelectric legs to further aid metallization contact therewith;
depositing conductive interconnects directly on top of the sputter deposited barrier metal layer to connect all of the plurality of pairs of the N-type thermoelectric legs and the P-type thermoelectric legs to one another to form the thermoelectric module;
encapsulating the formed thermoelectric module with an elastomer to render flexibility thereto; and
utilizing a temperature gradient perpendicular to a plane of the surface of the metal clad laminate of the formed thermoelectric module to derive thermoelectric power from a system element.

17. The method of claim 16, comprising one of: Cr, Ni and Au being the barrier metal layer.

18. The method of claim 16, further comprising depositing the conductive interconnects through at least one of: screen printing conductive forms of ink on the sputter deposited barrier metal layer and doctor blading thereof.

19. The method of claim 16, further comprising:
depositing a moisture barrier thin film on the formed thermoelectric module prior to encapsulation thereof with the elastomer; and
providing the encapsulation through the elastomer around the deposited moisture barrier thin film.

20. The method of claim 16, comprising encapsulating the formed thermoelectric module with the elastomer based on one of: doctor blading and spin coating.
